(19) United States
(12) Patent Application Publication
(10) Pub. No.: US 2026/0271770 A1
(43) Pub. Date: Sep. 10, 2026

(54) MANUFACTURING METHOD OF SEMICONDUCTOR DEVICE

(71) Applicant: Alliance Material Co., Ltd., Hsinchu County (TW)

(72) Inventors: Hsueh Chung Wu, Hsinchu County (TW); Chun Fa Chen, Hsinchu County (TW); Chi Hua Huang, Hsinchu County (TW); Chin Kai Lin, Hsinchu County (TW); Chen Ju Lee, Hsinchu County (TW); Shi Rou Xie, Hsinchu County (TW); Xuan You Chen, Hsinchu County (TW); Kuan Chun Hu, Hsinchu County (TW)

(73) Assignee: Alliance Material Co., Ltd., Hsinchu County (TW)

(21) Appl. No.: 19/305,805

(22) Filed: Aug. 21, 2025

(30) Foreign Application Priority Data
Mar. 4, 2025 (TW) 114107903

(51) Int. Cl. H01L 21/56; H01L 21/683

(52) U.S. Cl. CPC H10W 74/019; H10P 72/7402; H10P 72/7412; H10P 72/7442

(57) ABSTRACT

A manufacturing method of a semiconductor device includes at least the following steps. A semiconductor structure is provided. The semiconductor structure includes a redistribution layer, a chip, and a molding layer. The redistribution layer has a first surface and a second surface opposite to each other. The chip is disposed on the first surface. The chip is electrically connected to the redistribution layer. The molding layer encapsulates the chip. Next, a bonding process is performed, so that an adhesive film directly contacts the molding layer of the semiconductor structure. The adhesive film is used to provide an inward pulling force to the semiconductor structure. Then, the adhesive film is removed.

### CROSS-REFERENCE TO RELATED APPLICATION

This application claims the priority benefit of Taiwan application serial no. 114107903, filed on Mar. 4, 2025. The entirety of the above-mentioned patent application is hereby incorporated by reference herein and made a part of this specification.

### BACKGROUND

### Technical Field

The disclosure relates to a manufacturing method of a semiconductor device.

### Description of Related Art

During the manufacturing process of a semiconductor structure, a temporary carrier is often used in steps such as forming a redistribution layer to provide required functions such as support, and the temporary carrier is removed after a molding layer is formed. However, the removal of the temporary carrier often causes large warpage, which has an adverse effect on subsequent processes, thereby affecting product yield.

### SUMMARY

The disclosure provides a manufacturing method of a semiconductor device for effectively improving warpage of a semiconductor structure, thereby increasing production yield of a product.

A manufacturing method of a semiconductor device of the disclosure includes at least the following steps. A semiconductor structure is provided. The semiconductor structure includes a redistribution layer, a chip, and a molding layer. The redistribution layer has a first surface and a second surface opposite to each other. The chip is disposed on the first surface. The chip is electrically connected to the redistribution layer. The molding layer encapsulates the chip. A bonding process is performed, so that an adhesive film directly contacts the molding layer of the semiconductor structure. The adhesive film is used to provide an inward pulling force to the semiconductor structure. The adhesive film is removed.

In an embodiment of the disclosure, the adhesive film includes a balance portion and a delamination portion, the delamination portion is disposed between the semiconductor structure and the balance portion, and the adhesive film is removed through the delamination portion.

In an embodiment of the disclosure, before the adhesive film is removed through the delamination portion, multiple external terminals are formed on the second surface.

In an embodiment of the disclosure, the delamination portion is separated from the semiconductor structure through performing a light irradiation process.

In an embodiment of the disclosure, a wavelength range of light in the light irradiation process is between 200 nanometers and 420 nanometers.

In an embodiment of the disclosure, before performing the bonding process, at least one axial tension is provided to the adhesive film to provide the pulling force after performing the bonding process.

In an embodiment of the disclosure, the balance portion of the adhesive film is composed of a first base material and a first adhesion layer, the first adhesion layer is disposed between the delamination portion and the first base material, and a material of the first base material includes polyimide.

In an embodiment of the disclosure, the balance portion of the adhesive film includes a regulating layer, a value range of a coefficient of thermal expansion of the regulating layer is between 20 ppm/° C. and 300 ppm/° C., and a heating process is performed after performing the bonding process.

In an embodiment of the disclosure, the balance portion of the adhesive film is composed of a second adhesion layer and the regulating layer, and the second adhesion layer is disposed between the regulating layer and the delamination portion.

In an embodiment of the disclosure, the balance portion of the adhesive film is composed of a second base material, a third adhesion layer, and the regulating layer, the third adhesion layer is disposed between the delamination portion and the second base material, and the second base material is disposed between the third adhesion layer and the regulating layer.

Based on the above, the disclosure may flexibly adjust the warping state of the semiconductor structure through the pulling force continuously provided after the adhesive film is directly bonded to the molding layer of the semiconductor structure, so that the warped semiconductor structure receives a reverse stress and shrinks. In this way, the warpage of the semiconductor structure may be effectively reduced, so that subsequent processes may be smoothly performed, thereby improving the production yield of the product.

In order for the features and advantages of the disclosure to be more comprehensible, the following specific embodiments are described in detail in conjunction with the drawings.

### BRIEF DESCRIPTION OF THE DRAWINGS

FIG. 1 is a flowchart of a manufacturing method of a semiconductor device according to some embodiments of the disclosure.

FIG. 2A and FIG. 2B are partial schematic diagrams of a manufacturing method of a semiconductor device according to some embodiments of the disclosure.

FIG. 3 is a schematic diagram of a regulating process of an adhesive film and a semiconductor structure according to some embodiments of the disclosure.

FIG. 4 is a schematic diagram of the adhesive film and the semiconductor structure after regulation according to some embodiments of the disclosure.

FIG. 5 is a schematic diagram of an intermediate stage of a manufacturing method of a semiconductor device according to some embodiments of the disclosure.

FIG. 6 is a cross-sectional schematic diagram of an adhesive film used in FIG. 5 according to an embodiment.

FIG. 7 is a schematic diagram of an intermediate stage of a manufacturing method of a semiconductor device according to some embodiments of the disclosure.

FIG. 8 is a cross-sectional schematic diagram of an adhesive film used in FIG. 7 according to an embodiment.

FIG. 9 is a cross-sectional schematic diagram of an adhesive film used in FIG. 7 according to another embodiment.

FIG. 10 is a top view during an actual test performed according to an embodiment.

FIG. 11 is a side view of changes in warpage before performing a heating process and after performing the heating process according to an embodiment.

FIG. 12A and FIG. 12B are partial schematic diagrams of a manufacturing method of a semiconductor device according to some embodiments of the disclosure.

FIG. 13 is a cross-sectional schematic diagram of a delamination portion of an adhesive film used in FIG. 12A and FIG. 12B according to an embodiment.

### DESCRIPTION OF THE EMBODIMENTS

The disclosure will be more fully described with reference to the drawings of the embodiments. However, the disclosure may be embodied in many different forms and should not be construed as being limited to the embodiments described herein. The thickness, the size, or the dimensions of layers or regions in the drawings may be exaggerated for clarity. The same or similar reference numerals represent the same or similar elements, which will not be reiterated one by one in the following paragraphs.

Unless otherwise specified, the term “between” for defining a value range in the specification is intended to cover a range equal to the endpoint values and between the endpoint values. For example, a size range between a first value and a second value means that the size range may cover the first value, the second value, and any value between the first value and the second value.

Unless otherwise defined, all terms (including technical and scientific terms) used herein have the same meanings as commonly understood by persons of ordinary skill in the art to which the disclosure belongs.

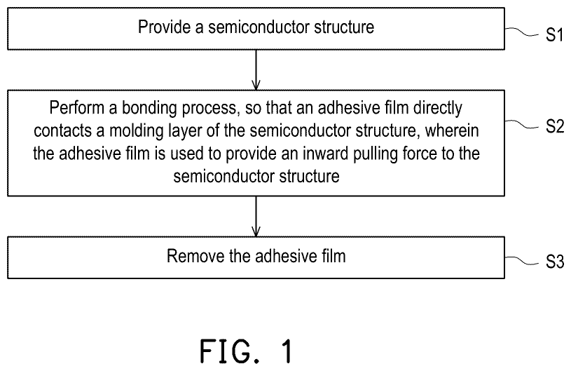

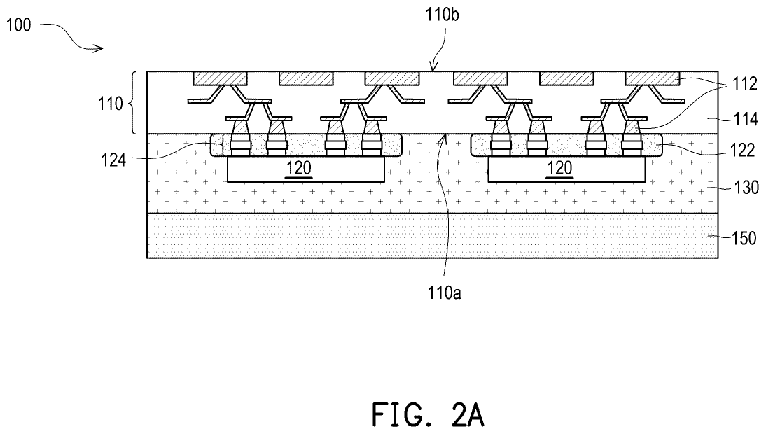

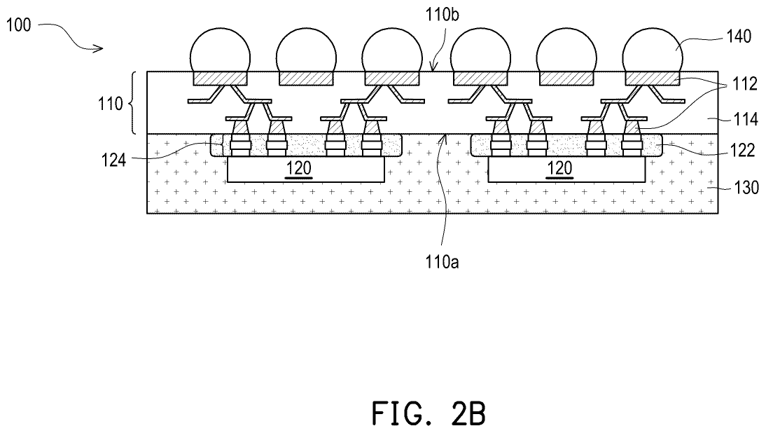

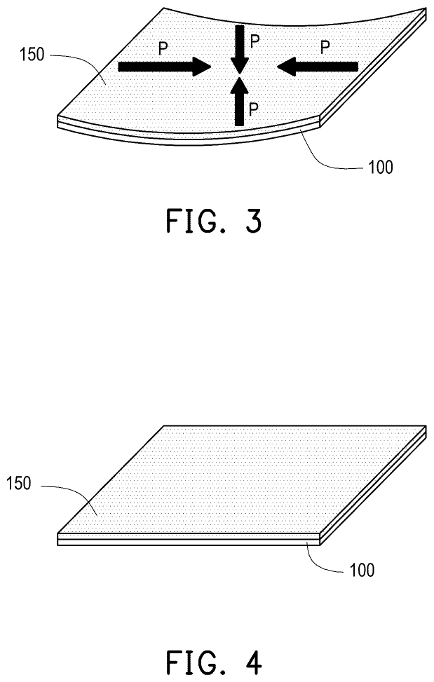

FIG. 1 is a flowchart of a manufacturing method of a semiconductor device according to some embodiments of the disclosure. FIG. 2A and FIG. 2B are partial schematic diagrams of a manufacturing method of a semiconductor device according to some embodiments of the disclosure. FIG. 3 is a schematic diagram of a regulating process of an adhesive film and a semiconductor structure according to some embodiments of the disclosure. FIG. 4 is a schematic diagram of the adhesive film and the semiconductor structure after regulation according to some embodiments of the disclosure. It should be noted that for the sake of clarity, FIG. 2A and FIG. 2B do not show the state change of warpage, and the corresponding state change of warpage may be as shown in FIG. 3 and FIG. 4.

Please refer to FIG. 1 to FIG. 4. Corresponding to step S1, a semiconductor structure 100 is provided. For example, the semiconductor structure 100 includes a redistribution layer (RDL) 110 having a first surface 110a and a second surface 110b, a chip 120 disposed on the first surface 110a, and a molding layer 130 encapsulating the chip 120, wherein the chip 120 is electrically connected to the redistribution layer 110. Here, the semiconductor structure 100 may be a fan-out wafer level package (FOWLP) or a fan-out panel level package (FOPLP).

In an embodiment, the semiconductor structure 100 is formed by the following steps.

For example, first, multiple conductive layers 112 and multiple insulating layers 114 surrounding the conductive layers 112 are alternately deposited on a temporary carrier (for example, glass, not shown) to form the redistribution layer 110, wherein the conductive layer 112 may be formed using a suitable conductive material through physical vapor deposition (PVD), chemical vapor deposition (CVD), electroplating, sputtering, or other suitable deposition processes, and the insulating layer 114 may be formed using a suitable insulating material through physical vapor deposition, chemical vapor deposition, spin coating, or other suitable deposition processes. Next, one or more chips 120 are bonded to the redistribution layer 110, and an underfill material 122 is formed in a gap between the chip 120 and the redistribution layer 110 to protect a contact 124 between the chip 120 and the redistribution layer 110. Then, the molding layer 130 is formed to package the chip 120 on the redistribution layer 110. After these steps, the temporary carrier may be removed to expose the second surface 110b of the redistribution layer 110.

For example, due to the mismatch in coefficients of thermal expansion between the molding layer 130 and the redistribution layer 110, large warpage (such as a middle part of the semiconductor structure 100 being recessed to present a smiley face state) may occur during a manufacturing process due to a high temperature process, which may affect the production yield of a product, wherein the material of the molding layer 130 includes an epoxy molding compound (EMC), a silicone molding compound (SMC), or other molding materials suitable for molding processes.

Next, in order to improve the warpage of the semiconductor structure 100, corresponding to step S2, a bonding process is performed, so that an adhesive film 150 directly contacts the molding layer 130 of the semiconductor structure 100, wherein the adhesive film 150 is used to provide an inward pulling force P to the semiconductor structure 100, as shown in FIG. 3. Accordingly, as shown in FIG. 4, through the pulling force P continuously provided after the adhesive film 150 is bonded to the semiconductor structure 100, the warping state of the semiconductor structure 100 may be flexibly regulated, so that the warped semiconductor structure 100 receives a reverse stress and shrinks. In this way, the warpage of the semiconductor structure 100 may be effectively reduced, so that subsequent processes (for example, dry etching, wet etching, ball mounting, reflow, flux cleaning, or the like) may be smoothly performed, thereby improving the production yield of the product. In addition, after the warpage is balanced, corresponding to step S3, the adhesive film 150 may be removed through a suitable manner. Here, the timing of removal may depend on the specific design of the adhesive film 150. For example, in the embodiment, as shown in FIG. 2A and FIG. 2B, the adhesive film 150 may be removed before multiple external terminals 140 are formed on the second surface 110b. In this way, the adhesive film 150 may not need to undergo a high temperature process such as reflow, so the adhesive film 150 may not need to be made of a material with excellent heat resistance, but the disclosure is not limited thereto.

It should be noted that although the semiconductor structure 100 shown in FIG. 4 shrinks to approach the horizontal state, the disclosure is not limited thereto. The degree of shrinking of the semiconductor structure 100 may be determined according to actual conditions, which all fall within the protection scope of the disclosure, as long as the pulling force P reverse to the warpage is received by the semiconductor structure 100. In addition, FIG. 2A and FIG. 2B are only exemplary illustrations, and the disclosure does not limit the specific details (for example, materials, formation methods, etc.) of conventional components (for example, the redistribution layer 110, the chip 120, the molding layer 130, the external terminal 140, or other suitable components not shown) in the semiconductor structure 100. The configuration of the components in the drawings is also only exemplary. In other words, the redistribution layer 110, the chip 120, the molding layer 130, the external terminal 140, and the configuration relationships therebetween may be all selected according to actual product requirements, which all fall within the protection scope of the disclosure, as long as the warpage may occur in the semiconductor structure 100.

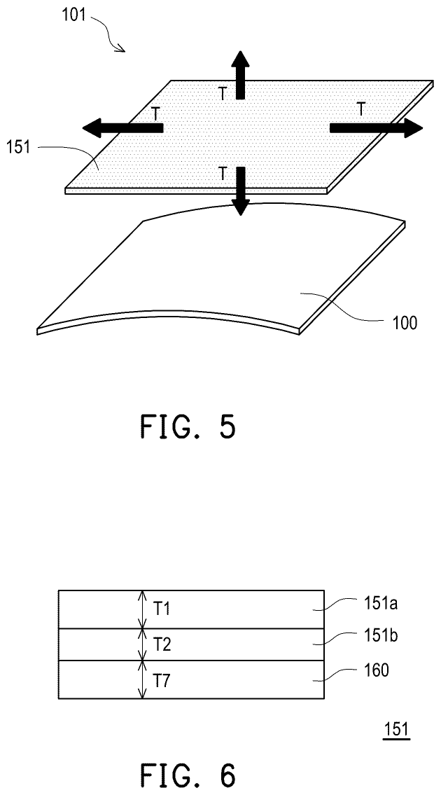

FIG. 5 is a schematic diagram of an intermediate stage of a manufacturing method of a semiconductor device according to some embodiments of the disclosure. FIG. 6 is a cross-sectional schematic diagram of an adhesive film used in FIG. 5 according to an embodiment.

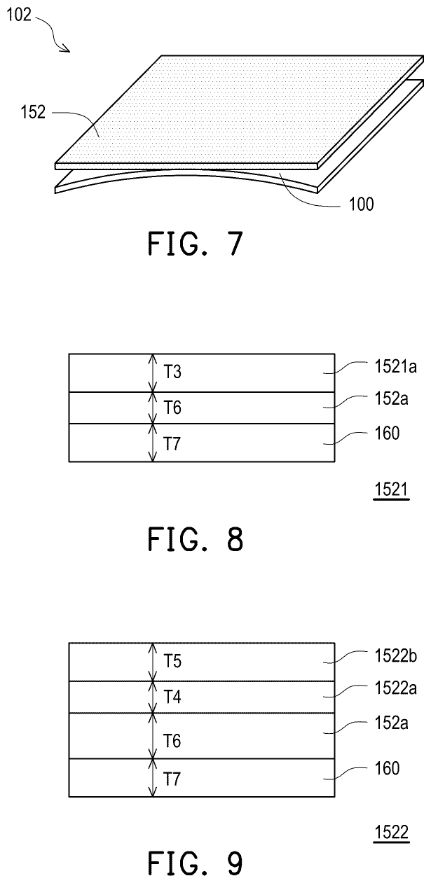

FIG. 7 is a schematic diagram of an intermediate stage of a manufacturing method of a semiconductor device according to some embodiments of the disclosure. FIG. 8 is a cross-sectional schematic diagram of an adhesive film used in FIG. 7 according to an embodiment. FIG. 9 is a cross-sectional schematic diagram of an adhesive film used in FIG. 7 according to another embodiment.

FIG. 5 to FIG. 9 will be used to respectively disclose specific implementation of the intermediate stage of the manufacturing method of various semiconductor devices, but the disclosure is not limited thereto. As long as there is a pulling force generated by an adhesive film on a semiconductor structure, the same falls within the protection scope of the disclosure, wherein FIG. 5 and FIG. 6 are used to illustrate specific implementation of generating the inward pulling force P on the semiconductor structure 100 through introducing an external force and the adhesive film used therewith, and FIG. 7 to FIG. 9 are used to illustrate specific implementation of generating the inward pulling force P on the semiconductor structure 100 through characteristics of a material and the adhesive film used therewith.

In the embodiment of FIG. 5, stage 101 before performing the bonding process is shown, and the adhesive film 150 of FIG. 2A, FIG. 2B, FIG. 3, and FIG. 4 may be implemented through an adhesive film 151. For example, before the adhesive film 151 is bonded to the semiconductor structure 100, at least one axial tension T may be provided to the adhesive film 151. In this way, the adhesive film 151 with the tension T may rebound and shrink when bonded to the semiconductor structure 100 to generate the inward pulling force P on the semiconductor structure 100, so as to flatten the warped semiconductor structure 100 and provide the reverse stress, so that the warpage may be effectively reduced.

In some embodiments, the value range of the tension T is between 1 Newton/centimeter (N/cm) and 30 N/cm, and at least one axial direction is the X-axis, the Y-axis, or a combination thereof. For example, the tension T may be introduced in one or more axial directions, and the tension T in the axial directions may be the same or different. Therefore, by adopting such manner, the warpage at different positions on the semiconductor structure 100 may be adjusted to achieve improved regulation. Based on this, when the semiconductor structure 100 has a structure with a long side and a short side, the tension film bonding manner of the disclosure may be more competitive. Here, the tension T may be provided through a suitable tension film bonding apparatus, but the disclosure is not limited thereto. For example, the tension film bonding apparatus may have a clamp, and the adhesive film 151 may be first clamped by the clamp and given the required tension T through a displacement of the clamp, the clamp being subjected to air pressure, etc., and then bonded to the semiconductor structure 100. However, it should be noted that the displacement corresponding to the tension T may be determined according to the actual product, but the disclosure is not limited thereto.

In the embodiment, since the manner for regulating the warpage is based on the introduction of the external force (tension T), the adhesive film 151 used may not have significant shrinkage. For example, in FIG. 6, the adhesive film 151 is composed of a base material 151a and an adhesion layer 151b. The base material 151a may be bonded to the semiconductor structure 100 through the adhesion layer 151b, and the material of the base material 151a may include polyimide (PI) with good heat resistance but poor shrinkage. On the other hand, a thickness T1 of the base material 151a is between 0.025 mm and 0.125 mm (for example, 0.05 mm), but the disclosure is not limited thereto.

In addition, the material of the adhesion layer 151b includes butyl rubber, isoprene rubber, chloroprene rubber, ethylene-vinyl acetate copolymer, ethylene-acrylic acid copolymer, ethylene-acrylate copolymer, polybutadiene resin, polycarbonate resin, thermoplastic polyimide resin, phenoxy resin, acrylic resin, polyethylene terephthalate, saturated polyester resin of polybutylene terephthalate, fluorocarbon resin, or a combination thereof, and a thickness T2 of the adhesion layer 151b is between 0.01 mm and 0.1 mm (for example, 0.1 mm), but the disclosure is not limited thereto.

In the embodiment of FIG. 7, a heating process is further performed after the bonding process. Therefore, FIG. 7 shows stage 102 between performing the bonding process and performing a baking process, and the adhesive film 150 of FIG. 2A, FIG. 2B, FIG. 3, and FIG. 4 may be implemented through an adhesive film 152. For example, the adhesive film 152 has a regulating layer, and the value range of the coefficient of thermal expansion (CTE) of the regulating layer is between 20 ppm/° C. and 300 ppm/° C. In this way, before the heating process is performed, even the regulating layer is already bonded to the semiconductor structure 100, the pulling force P is not yet provided at this time, as shown in FIG. 7. After the heating process is performed, the regulating layer shrinks based on the characteristics of the material and provide the pulling force P to the semiconductor structure 100, so as to flatten the warped semiconductor structure 100 and provide the reverse stress, so that the warpage may be effectively reduced.

In an embodiment, as shown in FIG. 8, the adhesive film 152 may be an adhesive film 1521, which may be composed of an adhesion layer 152a and a regulating layer 1521a. The regulating layer 1521a may be bonded to the semiconductor structure 100 through the adhesion layer 152a, wherein the regulating layer 1521a includes polyetherimide (PEI), polyetheretherketone (PEEK), polyphenylene sulfide (PPS), polyethylene naphthalate (PEN), or a combination thereof with a larger coefficient of thermal expansion, thereby having improved shrinkage, and the material of the regulating layer 1521a may not include polyimide. For example, when the temperature of the baking process is greater than 200° C., polyetherimide and polyetheretherketone are preferred, and when the temperature of the baking process is less than 200° C., polyphenylene sulfide and polyethylene naphthalate are preferred, but the disclosure is not limited thereto. For example, in terms of the selection of the above materials, the baking temperature and the warpage regulating ability increase in a linear relationship. In other words, in terms of the selection of the above materials, the adhesive film 1521 may have good thermal stability, which may further improve product yield, but the disclosure is not limited thereto.

On the other hand, when a thickness T3 of the regulating layer 1521a is thicker, the warpage regulating ability thereof is also improved accordingly. For example, the thickness of the regulating layer 1521a may be between 25 μm and 350 μm (for example, 0.05 mm), but the disclosure is not limited thereto.

In another embodiment, as shown in FIG. 9, the adhesive film 152 may be an adhesive film 1522, which may be composed of a base material 1522a, the adhesion layer 152a, and a regulating layer 1522b. The adhesive film 1522 is bonded to the semiconductor structure 100 through the adhesion layer 152a. The adhesion layer 152a is disposed between the semiconductor structure 100 and the base material 1522a. The base material 1522a is disposed between the adhesion layer 152a and the regulating layer 1522b, wherein the base material 1522a includes polyimide, and the regulating layer 153B includes an epoxy molding compound, phenolic resin, or a combination thereof with improved shrinkage. Here, a thickness T4 of the base material 1522a is between 0.025 mm and 0.1 mm, and a thickness T5 of the regulating layer 1522b is between 0.035 mm and 0.35 mm, but the disclosure is not limited thereto.

In some embodiments, a thickness T6 of the adhesion layer 152a in the adhesive film 1521 or 1522 is between 0.01 mm and 2 mm (for example, 0.1 mm), and the adhesion layer 152a includes an adhesive composition. The adhesive composition includes an acrylic curable compound and a functional monomer in a suitable ratio.

In some embodiments, a monomer of the acrylic curable compound may be a compound having a (meth)acrylate group. For example, the (meth)acrylate-based compound may include a compound selected from compounds composed of methyl(meth)acrylate, ethyl(meth)acrylate, n-propyl(meth)acrylate, isopropyl(meth)acrylate, n-butyl(meth)acrylate, t-butyl(meth)acrylate, sec-butyl(meth)acrylate, pentyl(meth)acrylate, 2-ethylhexyl(meth)acrylate, 2-ethylbutyl(meth)acrylate, n-octyl(meth)acrylate, isooctyl(meth)acrylate, isononyl(meth)acrylate, lauryl(meth)acrylate, tetradecyl(meth)acrylate, acrylic acid, methacrylic acid, 2-(meth)acryloyloxy acetic acid, 3-(meth)acryloyloxy propyl acid, 4-(meth)acryloyloxy butyric acid, 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 2-hydroxy ethylene glycol(meth)acrylate, 2-hydroxy propylene glycol(meth)acrylate, and a combination thereof.

In some embodiments, the acrylic curable compound may be an acrylic photocurable compound, and the adhesive composition may further include a photoinitiator. For example, the photoinitiator is an organic photoinitiator such as oxime (for example, acyloxime, ketoneoxime, or other oximes), benzoin and derivatives (for example, benzoin, benzoin dimethyl ether, benzoin ethyl ether, benzoin isopropyl ether, benzoin butyl ether), benzil, alkyl phenone (for example, α-hydroxyalkyl phenone (HAPK)), acyl phosphorus oxide (for example, alkyl diacyl phosphine oxide), benzophenone, and thioxanthen-9-one; a cationic photoinitiator such as diazonium salt, diaryliodonium salt, triarylsulfonium salt, alkylsulfonium salt, aromatic iron salt, sulfonyl ketone, and triarylsiloxane; a derivative thereof, or a combination thereof.

In some embodiments, the functional monomer may be a bridging agent, a heat resistant monomer, and/or a diluent monomer.

In some embodiments, the adhesive composition is organic solvent-free. The organic solvent is, for example, n-hexane, toluene, xylene, methyl isobutyl ketone, etc., which may be used alone or in combination. In this way, the adhesion layer 152a may reduce contamination of a semiconductor process (for example, baking, heating deposition, exposure and development, or other semiconductor processes with high temperature or low pressure) when used during the process.

In some embodiments, the adhesion layer 152a is, for example, a pressure-sensitive adhesive. For example, the material of the adhesion layer 152a includes acrylic resin, polyurethane resin, polysiloxane resin, a combination of the above materials, or other suitable polymer materials.

In some embodiments, the adhesion layer 152a may include a photosensitive material, and adhesion of the adhesion layer 152a is reduced after being exposed to light (for example, ultraviolet light), so that the adhesive may be removed through light exposure during a subsequent process. Alternatively, the adhesion layer 152a may include a thermosetting material, and adhesion of the adhesion layer 152a is reduced after being heated, so that the adhesive may be removed through heating during a subsequent process. Alternatively, the adhesion layer 152a may include a cold dissociation material, and adhesion of the adhesion layer 152a is reduced when cooled below the glass transition temperature, so that the adhesive may be removed through cooling during a subsequent process.

The adhesion layer 152a is suitable for adhering a dissociation material layer to an adhered object (for example, a process element). The adherence manner between the adhesion layer 152a and other materials includes physical adsorption, diffusion, electrostatic adsorption, mechanical interlocking, and chemical bonding.

In some embodiments, the raw materials of the adhesion layer 152a include an oligomer, a monomer, an initiator, and an additive. For example, the cured adhesion layer 152a includes acrylic resin or other suitable materials. In some embodiments, the oligomer includes polyester acrylate, polyurethane acrylate, polyether acrylate, or a combination thereof.

In some embodiments, in the raw materials of the adhesion layer 152a, the weight ratio of the monomer is 20 wt % to 50 wt %, such as 20 wt %, 30 wt %, 40 wt %, 50 wt %, or any range from 20 wt % to 50 wt %. In some embodiments, the monomer includes a monofunctional monomer, a bifunctional monomer, a multifunctional monomer, or a combination thereof.

In some embodiments, the monofunctional monomer is, for example, isodecyl acrylate (IDA), tetrahydrofurfuryl acrylate (THFA), isobornyl acrylate (IBOA), or 2-phenoxy ethyl acrylate (PHEA), wherein the chemical structures of isodecyl decaacrylate, tetrahydrofurfuryl acrylate, isobornyl acrylate, and 2-phenoxy ethyl acrylate are respectively shown in (Formula 2), (Formula 3), (Formula 4), and (Formula 5) below.

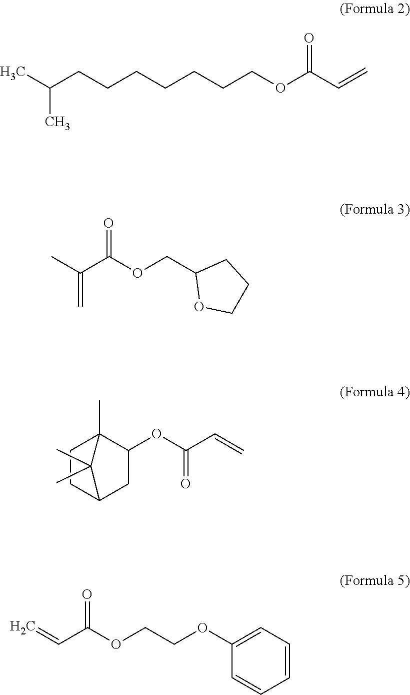

In some embodiments, the bifunctional monomer is, for example, hexanediol diacrylate (HDDA) or polyethylene glycol (600) diacrylate (PEG (600) DA), wherein the chemical structures of hexanediol diacrylate and polyethylene glycol (600) diacrylate are respectively shown in (Formula 6) and (Formula 7) below.

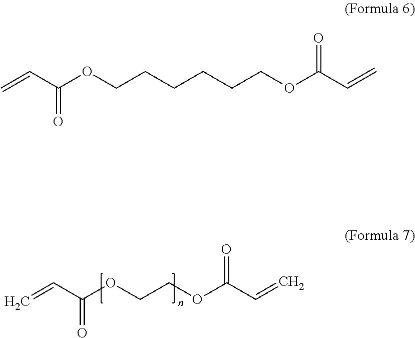

In some embodiments, the multifunctional monomer is, for example, trimethylolpropane triacrylate (TMPTA) or dipentaerythritol hexaacrylate (DPHA), wherein the chemical structures of trimethylolpropane triacrylate and dipentaerythritol hexaacrylate are respectively shown in (Formula 8) and (Formula 9) below.

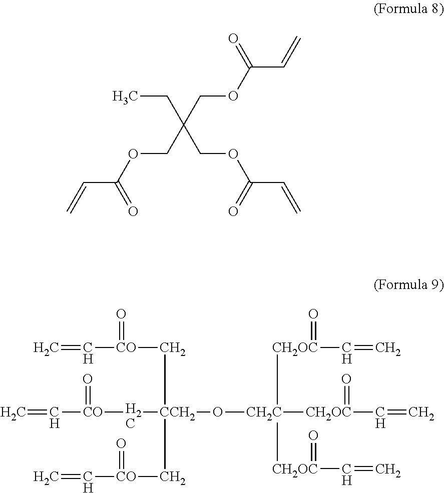

The initiator among the raw materials of the adhesion layer 152a is suitable for initiating polymerization and bridging reactions. For example, one or more photoinitiators are used to induce the polymerization and bridging reactions of the monomer and the oligomer. In some embodiments, the photoinitiator includes a free radical photoinitiator. In some embodiments, in the raw materials of the adhesion layer 152a, the weight ratio of the photoinitiator is less than or equal to 10 wt %, such as 9 wt %, 8 wt %, 7 wt %, 6 wt %, 5 wt %, 4 wt %, 3 wt %, 2 wt %, 1 wt %, or any value below 10 wt %. In some embodiments, the photoinitiator is suitable for absorbing ultraviolet light to initiate the polymerization reaction.

In some embodiments, polyester acrylate resin, polyurethane acrylate resin, or polyether acrylate resin uses the free radical photoinitiator, such as 1-hydroxycyclohexyl phenyl ketone or phenyl bis(2,4,6-trimethylbenzoyl)-phosphine oxide, whose chemical structures are respectively as shown in (Formula 10) and (Formula 11) below.

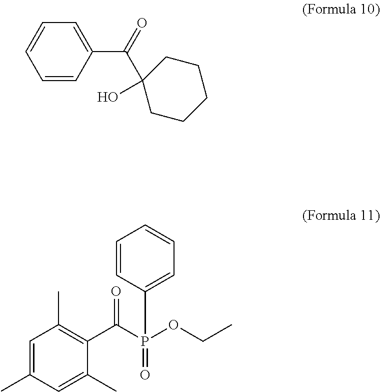 [SMILES: O=C(c1ccccc1)C1(O)CCCCC1 ; CCOP(=O)(C(=O)c1c(C)cc(C)cc1C)c1ccccc1]

In some embodiments, the raw materials of the adhesion layer 152a further include an additive. The additive includes, for example, a surface active agent, a stabilizer, a dye, a solvent, or other materials. In some embodiments, the additive includes, for example, conductive particles, conductive fibers, conductive polymer, or other suitable conductive materials. Therefore, the adhesion layer 152a has an antistatic function. In some embodiments, the additive includes a difunctional acrylic oligomer (for example, an aliphatic urethane diacrylate oligomer). The difunctional acrylic oligomer may improve the bridging properties of the adhesion layer 152a, thereby enhancing chemical resistance and heat resistance of the adhesion layer 152a, and reducing any residual adhesive generated after the adhesion layer 152a is removed. In some embodiments, the additive includes a difunctional monomer (for example, ethoxylated bisphenol A diacrylate, 1,6-hexanediol diacrylate, or a combination thereof). The difunctional monomer may further enhance the bridging strength of the adhesion layer 152a.

In the following embodiment, it is specifically described that the adhesive film 152 of the disclosure may generate a reverse pulling force on the warped semiconductor structure (for example, a wafer) after the heating process, which may reduce the warpage of the semiconductor structure. However, the disclosure is not limited at all to the following embodiment.

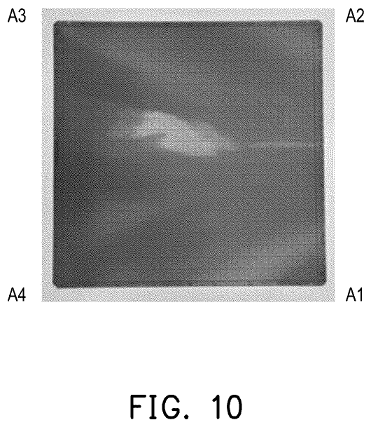

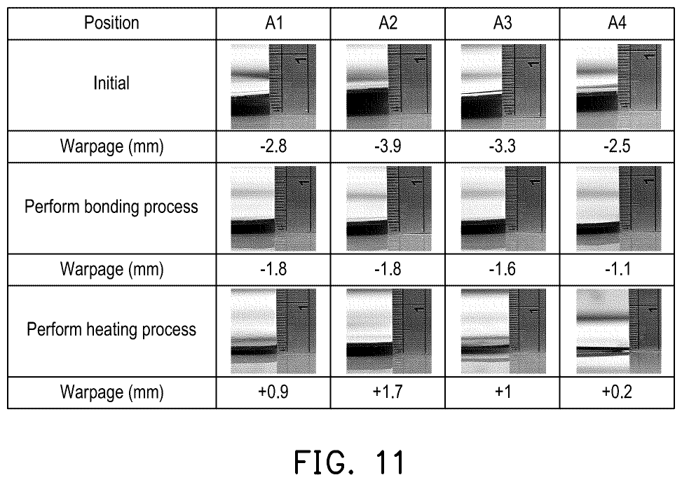

FIG. 10 is a top view during an actual test performed according to an embodiment. FIG. 11 is a side view of changes in warpage before performing a heating process and after performing the heating process according to an embodiment. In an embodiment, initial wafers used have substantially the same warpage, and the test conditions are substantially the same. Specifically, in the embodiment, in order to use the wafers with the same warpage for testing, the heating condition is 150° C./1 hour to 250° C./1 hour, and the specific composition of the adhesive film is a base material with a thickness of 50 microns (um), whose material is polyetheretherketone and an adhesion layer with a thickness of 30 μm, whose material is acrylic (UV adhesion reducing adhesive). As shown in FIGS. 10, A1, A2, A3, and A4 in FIG. 10 represent four positions of the wafer, and FIG. 11 shows the change in the degree of warpage of the wafer before and after the wafer and the adhesive film bonded to the wafer are subjected to the above heating conditions, and directions of the warpage are represented by a positive sign (+) and a negative sign (−). In addition, as shown in FIG. 11, the change in appearance of the warpage is confirmed by actual measurement in the side view direction. It can be known from the drawing that the adhesive film provided by the disclosure may generate the reverse pulling force on the warped wafer.

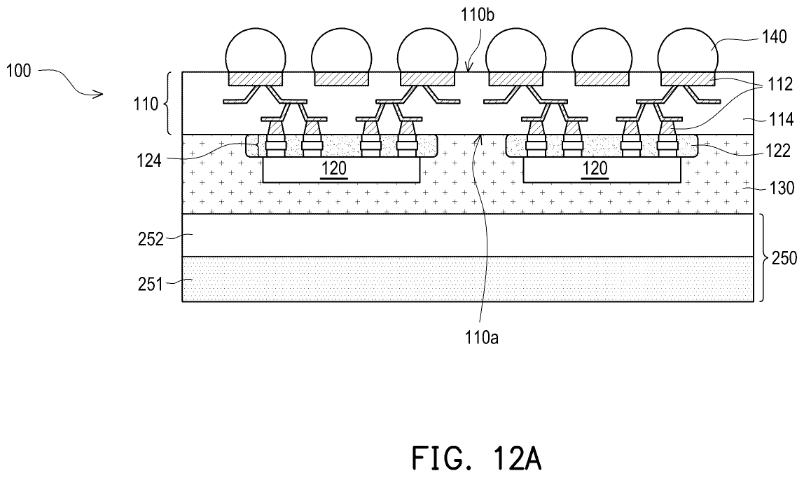

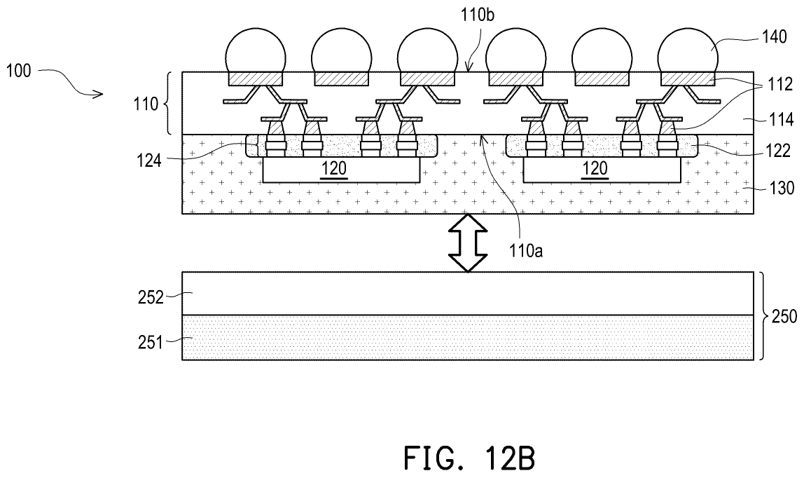

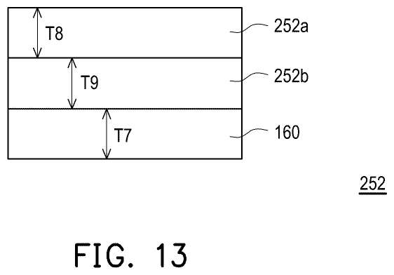

FIG. 12A and FIG. 12B are partial schematic diagrams of a manufacturing method of a semiconductor device according to some embodiments of the disclosure. FIG. 13 is a cross-sectional schematic diagram of a delamination portion of an adhesive film used in FIG. 12A and FIG. 12B according to an embodiment.

FIG. 12A is similar to FIG. 2A, except that an adhesive film 250 includes a balance portion 251 and a delamination portion 252. The delamination portion 252 is disposed between the semiconductor structure 100 and the balance portion 251, and as shown in FIG. 12B, the adhesive film 250 may be removed after the external terminals 140 are formed on the second surface 110b, and the adhesive film 250 may be removed through the delamination portion 252 (such as after a cutting process is performed). In this way, the structure after separation may be conveniently used by a pick and place manner, thereby having an automation advantage. In this case, the adhesive film 250 may be a material with excellent heat resistance (for example, a material that may withstand the reflow temperature of the external terminal 140), but the disclosure is not limited thereto. The adhesive film 250 may also be removed through the delamination portion 252 before forming the external terminal 140. In this case, the adhesive film 250 may be a material that is less heat resistant.

In some embodiments, the delamination portion 252 is separated from the semiconductor structure 100 through performing a light irradiation process. For example, light used in the light irradiation process may be ultraviolet (UV) light, so the wavelength range of the light in the irradiation process is between 200 nm and 420 nm, but the disclosure is not limited thereto.

In some embodiments, the balance portion 251 may be in any form of the adhesive film 151, the adhesive film 1521, or the adhesive film 1522, wherein in an unillustrated part, when the balance portion 251 is the adhesive film 151, the adhesion layer 151b is disposed between the delamination portion 252 and the base material 151a; when the balance portion 251 is the adhesive film 1521, the adhesion layer 152a is disposed between the regulating layer 1521a and the delamination portion 252; when the balance portion 251 is the adhesive film 1522, the adhesion layer 152a is disposed between the delamination portion 252 and the base material 1522a, and the base material 1522a is disposed between the adhesion layer 152a and the regulating layer 1522b.

In some embodiments, as shown in FIG. 13, the delamination portion 252 may be composed of a base material 252a and an adhesion layer 252b, and the base material 252a and the balance portion 251 may be bonded to the semiconductor structure 100 through the adhesion layer 252b. Here, a thickness T8 of the base material 252a is between 0.025 mm and 0.2 mm, and a thickness T9 of the adhesion layer 252b is between 0.02 mm and 0.1 mm, but the disclosure is not limited thereto.

In some embodiments, the material of the base material 252a includes polyethylene naphthalate (PEN), polyamide-imide (PAI), polyphenylsulfone (PPSU), polyetherimide (PEI), polyetheretherketone (PEEK), or the like.

In some embodiments, the adhesion layer 252b is composed of an acrylic adhesive, an ultraviolet resin monomer, a hardener, and a photoinitiator, wherein the weight ratio of the acrylic adhesive in the adhesion layer 252b is between 45 wt % and 75 wt %, the weight ratio of the ultraviolet resin monomer in the adhesion layer 252b is between 12 wt % and 18 wt %, the weight ratio of the hardener in the adhesion layer 252b is between 0.05 wt % and 5 wt %, and the weight ratio of the photoinitiator in the adhesion layer 252b is between 0.01 wt % and 2 wt %.

In some embodiments, the acrylic adhesive includes a polyacrylate copolymer and has a solid content of between 15% and 60%, a viscosity of between 100 cps and 60,000 cps, and a molecular weight of between 250 and 2,000,000.

In some embodiments, the functional group number of the UV resin monomer is between 1 and 15, the solid content is between 5% and 100%, the viscosity is between 10 cps and 800,000 cps (for example, 60,000 cps), and the molecular weight is between 250 and 2,000,000. For example, the UV resin monomer includes unsaturated polyester, epoxy acrylate, polyamino acrylate, polyester acrylate, polyether acrylate, acrylated polyacrylic resin, epoxy resin, photocurable polysiloxane, polyolefin resin, bisphenol A epoxy diacrylate (diluted in 20% TPGDA), bisphenol A epoxy diacrylate (diluted in 20% DPGDA), bisphenol A epoxy diacrylate (diluted in 40% TMP7EOTA), modified or unmodified epoxy acrylate, epoxy methacrylate, low viscosity 621A-80 (diluted in 25% TPGDA), epoxy soybean oil acrylate, or a combination thereof.

In some embodiments, the hardener includes isocyanate or an epoxy material, the solid content of the hardener is between 50% and 100%, and an NCO equivalent is between 5% and 23%. For example, the isocyanate includes 2,4-toluene diisocyanate, 80/20-toluene diisocyanate, 65/35-toluene diisocyanate, 4,4′-diphenylmethane diisocyanate, polymethylene polyphenyl polyisocyanate, xylylene diisocyanate, hexamethylene diisocyanate, 2,6-diisocyanatomethyl hexanoate, dimer fatty acid diisocyanate, diethyl fumarate diisocyanate, 2,2,4-trimethylhexane diisocyanate, isophorone diisocyanate, naphthalene-1,5-diisocyanate, methylcyclohexyl diisocyanate, dicyclohexylmethane diisocyanate, tetramethylxylylene diisocyanate, or a combination thereof.

In some embodiments, the reaction wavelength of the photoinitiator is between 200 nm and 420 nm, and the photoinitiator includes IRGACURE 184, DAROCUR 1173, TPO, or a combination thereof.

In some embodiments, as shown in FIG. 6, FIG. 8, FIG. 9, and FIG. 13, a release layer 160 may be formed on the adhesion layer 151b of the adhesive film 151, the adhesion layer 152a of the adhesive film 152 (for example, the adhesive films 1521 and 1522), or the adhesion layer 252a of the delamination portion 252 to enhance the convenience of use, wherein the release layer 160 is torn off when the device is to be used. Here, the material of the release layer 160 may be polyethylene terephthalate (PET), polyolefins (PO), cast polypropylene (CPP), release paper, or the like, and a thickness T7 of the release layer 160 is between 0.025 mm and 0.175 mm (for example, 0.038 mm), but the disclosure is not limited thereto.

In summary, the disclosure may flexibly adjust the warping state of the semiconductor structure through the pulling force continuously provided after the adhesive film is directly bonded to the molding layer of the semiconductor structure, so that the warped semiconductor structure receives the reverse stress and shrinks. In this way, the warpage of the semiconductor structure may be effectively reduced, so that the subsequent processes may be smoothly performed, thereby improving the production yield of the product.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A manufacturing method of a semiconductor device, comprising:
providing a semiconductor structure, wherein the semiconductor structure comprises:
a redistribution layer, having a first surface and a second surface opposite to each other;
a chip, disposed on the first surface, wherein the chip is electrically connected to the redistribution layer; and
a molding layer, encapsulating the chip;
performing a bonding process, so that an adhesive film directly contacts the molding layer of the semiconductor structure, wherein the adhesive film is used to provide an inward pulling force to the semiconductor structure; and
removing the adhesive film.

2. The manufacturing method of the semiconductor device according to claim 1, wherein the adhesive film comprises a balance portion and a delamination portion, the delamination portion is disposed between the semiconductor structure and the balance portion, and the adhesive film is removed through the delamination portion.

3. The manufacturing method of the semiconductor device according to claim 2, wherein before the adhesive film is removed through the delamination portion, a plurality of external terminals are formed on the second surface.

4. The manufacturing method of the semiconductor device according to claim 2, wherein the delamination portion is separated from the semiconductor structure through performing a light irradiation process.

5. The manufacturing method of the semiconductor device according to claim 4, wherein a wavelength range of light in the light irradiation process is between 200 nanometers and 420 nanometers.

6. The manufacturing method of the semiconductor device according to claim 2, wherein before performing the bonding process, at least one axial tension is provided to the adhesive film to provide the pulling force after performing the bonding process.

7. The manufacturing method of the semiconductor device according to claim 6, wherein the balance portion of the adhesive film is composed of a first base material and a first adhesion layer, the first adhesion layer is disposed between the delamination portion and the first base material, and a material of the first base material comprises polyimide.

8. The manufacturing method of the semiconductor device according to claim 2, wherein the balance portion of the adhesive film comprises a regulating layer, a value range of a coefficient of thermal expansion of the regulating layer is between 20 ppm/° C. and 300 ppm/° C., and a heating process is performed after performing the bonding process.

9. The manufacturing method of the semiconductor device according to claim 8, wherein the balance portion of the adhesive film is composed of a second adhesion layer and the regulating layer, and the second adhesion layer is disposed between the regulating layer and the delamination portion.

10. The manufacturing method of the semiconductor device according to claim 8, wherein the balance portion of the adhesive film is composed of a second base material, a third adhesion layer, and the regulating layer, the third adhesion layer is disposed between the delamination portion and the second base material, and the second base material is disposed between the third adhesion layer and the regulating layer.
